(19) United States
(12) Patent Application Publication
(10) Pub. No.: US 2026/0059723 A1
(43) Pub. Date: Feb. 26, 2026

(54) CLOSED-TYPE HEAT-DISSIPATING-FIN-FREE COOLING-LIQUID-IMMERSED COOLING SYSTEM

(71) Applicant: Meng-Theng WANG, New Taipei City (TW)

(72) Inventor: Meng-Theng WANG, New Taipei City (TW)

(21) Appl. No.: 18/810,479

(22) Filed: Aug. 20, 2024

(51) Int. Cl. H05K 7/20; F03D 9/25; F03D 80/60

(52) U.S. Cl. CPC H05K 7/20927; H05K 7/20236; F03D 9/25; F03D 80/60; F05B 2220/706; F05B 2260/20

(57) ABSTRACT

includes a first heat exchange box, a second heat exchange box, and a refrigeration machine. The refrigeration machine includes a refrigerant pipe extending into the second heat exchange box to immerse in the cooling liquid. The refrigeration machine feeds a refrigerant to circulate and flow through the refrigerant pipe. Temperature-lowered refrigerant performs, through the refrigerant pipe, heat exchange with the cooling liquid of the second heat exchange box, and the cooling liquid of which the temperature is lowered is fed into the first heat exchange box to perform heat exchange with, and absorb heat from, a heat-generating body disposed therein, and the cooling liquid of which the temperature increases flows back into the second heat exchange box to perform heat exchange for lowering the temperature thereof so as to have the process cyclically repeated.

### BACKGROUND OF THE INVENTION

### (a) Technical Field of the Invention

The present invention relates to a cooling system that does not involve heat dissipating fins while fulfill high-efficiency heat dissipation.

### (b) Description of the Prior Art

Heat dissipation is an issue that has been frequently mentioned recently in the era of Industry 4.0 and information technology, because any equipment or device that requires work will generate heat. If the heat cannot be effectively removed in time, it will affect the operating efficiency in the least, and cause the work to stop in the worst case.

Taking wind power generation equipment as an example, a windmill is set up in an area having sufficient wind power. Fan blades of the windmill has a shaft that is connected to a generator through a gear mechanism. The fan blades, when blown by winds to rotate, drives the generator to rotate by means of the gear mechanism so as to generate electricity. In the process of converting wind power into mechanical force, and then converting mechanical force into electrical power, a certain degree of mechanical energy will be lost by friction between the gear mechanism and other components, thus reducing the efficiency of wind power generation. To this end, Taiwan Invention Patent No. I800422, which was previously filed by the present inventor, provides a fully magnetic levitation high-speed generator set, which has a main shaft set in a housing, and upper and lower ends of the main shaft are supported, in a suspending manner, on magnetic levitation support seats, and further, the lateral side of the shaft is supported by magnetic levitation bearings. The main shaft is also provided with at least one rotary disk to serve as a rotor of the generator. The rotary disk is provided with a plurality of induction magnets arranged along a circumference, and a plurality of windings are mounted to the housing as being arranged along the circumference of the main shaft to serve as a stator and connected to a power transmission line. The upper end of the main shaft is provided with a transmission mechanism, and the transmission mechanism is connected to a fan unit or a motor serving as a power source. The fan unit or the motor applies power to drive the main shaft to rotate, thereby driving the rotary disk to rotate to have the induction magnets rotate relative to the windings to generate an induced current. Supporting the main shaft in a fully magnetic levitation manner allows the main shaft to have the lowest impedance for rotating and achieving high-power electric output.

Although the fully magnetic levitation wind power generation device is a green energy device with higher power generation efficiency, the generator still has the problem of winding heating during operation. In order to overcome such a problem, traditionally, an outer casing of the generator is formed with a plurality of heat dissipating fins. The heat dissipating fins help expand the heat absorption and heat dissipation area of the outer casing to collaborate with air cooling to remove heat. However, such an arrangement for heat dissipation with heat dissipating fins combined with air cooling has become unsuitable for devices of large power.

On the other hand, in the era where AI computing power has increased significantly, higher-end chips generate more heat when operating. Traditional ways of cooling and heat dissipation can no longer meet the requirements. Therefore, liquid cooling technology has also been booming recently. The known techniques of liquid cooling are to immerse a heat-generating body in a non-conductive cooling liquid in a container, and a refrigeration device is set above the cooling liquid in the container. When the heat-generating body gives off heat, the cooling liquid that has a low boiling point is evaporated. The evaporated vapor is then condensed into a liquid state by refrigeration tubes and falls back down, and this operates cyclically.

### SUMMARY OF THE INVENTION

An object of the present invention is to provide a cooling system that does not involve heat dissipating fins and fulfill an effect of heat dissipation more efficiently.

The present invention provides a closed-type heat-dissipating-fin-free cooling-liquid-immersed cooling system, of which the technical solution comprises: a first heat exchange box, which contains therein a heat-generating body, the first heat exchange box comprising a first cooling liquid entry opening and a first cooling liquid exit opening; a second heat exchange box, which contains a cooling liquid, the second heat exchange box comprising a second cooling liquid entry opening and a second cooling liquid exit opening, wherein the second cooling liquid entry opening and the first cooling liquid exit opening are connected through a first pipe, and the second cooling liquid exit opening and the first cooling liquid entry opening are connected through a second pipe, and a pump is arranged on the second pipe; and a refrigeration machine, which is connected with a refrigerant pipe, the refrigerant pipe being extended into an interior of the second heat exchange box and immersed in the cooling liquid; wherein the refrigeration machine causes a refrigerant to circulate and flow through the refrigerant pipe to have temperature-lowered refrigerant perform, through the refrigerant pipe, heat exchange with the cooling liquid contained in the second heat exchange box, and the cooling liquid, of which temperature is lowered is drawn by the pump and fed through the second pipe into the first heat exchange box to carry out heat exchange with, and absorb heat from, the heat-generating body, and the cooling liquid of which the temperature increases, flows through the first pipe to return back into the second heat exchange box to carry out heat exchange again to lower down the temperature thereof, so as to proceed cyclically.

Preferably, the cooling liquid is a non-conductive cooling liquid. As such, windings of an electrical power generator and circuit boards on which electronic components and circuits are arranged can be immersed therein without causing damages.

In an embodiment of the present invention, the first heat exchange box is of a cylindrical form, and the first cooling liquid entry opening is formed so that an axis thereof is in a tangential direction of a circular arc sidewall. As such, the cooling liquid, when moving into the first heat exchange box, may flow along the circumference of the cylindrical form to fully absorb the heat generated by the heat-generating body and then flow back into the second heat exchange box.

In an embodiment of the present invention, the first cooling liquid exit opening is formed so that an axis thereof is in a direction perpendicular to the circular arc sidewall. As such, the cooling liquid, when flowing along the circumference of the cylindrical form of the first heat exchange box to flow out slightly slowly, may fully absorb the heat generated by the heat-generating body.

In an embodiment of the present invention, a main shaft hole is formed in a center of the cylindrical form of the first heat exchange box. As such, the first heat exchange box may be provided for receiving and containing an electrical power generator of a magnetic levitation power generation device, such that windings of the electrical power generator are completely immersed in the cooling liquid in the first heat exchange box, and a main shaft of the electrical power generator extends through the main shaft hole.

In an embodiment of the present invention, the first heat exchange box is of a rectangular parallelepiped form in which circuit boards on which chips are mounted are received.

The present invention provides the above-described cooling system, which has advantages of being free of leakage of coolant vapor and ensuring better cold-keeping for the cooling liquid circulating internally.

### BRIEF DESCRIPTION OF THE DRAWINGS

FIG. 1 is a schematic view showing a cooling system of the present invention.

FIG. 2 is a cross-sectional view taken along line II-II of FIG. 1, showing a structure of a first heat exchange box in a cylindrical form.

FIG. 3 is a schematic view showing an embodiment of the present invention, in which the first heat exchange box in the cylindrical form is installed in a magnetic levitation wind power.

FIG. 4 is a schematic view showing an embodiment of the present invention, in which circuit boards are immersed in a first heat exchange box in a rectangular parallelepiped form.

### DETAILED DESCRIPTION OF THE PREFERRED EMBODIMENTS

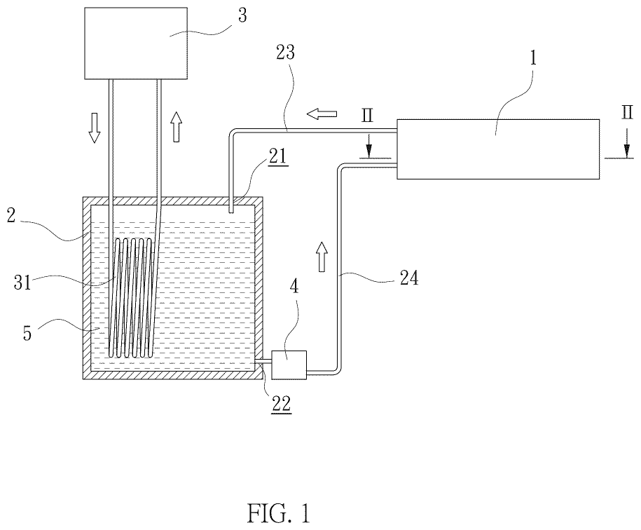

As shown in FIG. 1, the present invention provides a closed-type heat-dissipating-fin-free cooling-liquid-immersed cooling system, which comprises: a first heat exchange box 1, a second heat exchange box 2, and a refrigeration machine 3. The first heat exchange box 1 is a container that has an internal space 13 for containing a heat-generating body therein, and the first heat exchange box 1 comprises a first cooling liquid entry opening 11 and a first cooling liquid exit opening 12. The second heat exchange box 2 is a container that contains a cooling liquid 5, and the second heat exchange box 2 comprises a second cooling liquid entry opening 21 and a second cooling liquid exit opening 22. The second cooling liquid entry opening 21 and the first cooling liquid exit opening 12 are connected to each other by a first pipe 23, and the second cooling liquid exit opening 22 and the first cooling liquid entry opening 11 are connected to each other by a second pipe 24. A pump 4 is arranged on the second pipe 24. The refrigeration machine 3 is arranged outside of the second heat exchange box 2. The refrigeration machine 3 is connected with a refrigerant pipe 31, and the refrigerant pipe 31 is extended into an interior of the second heat exchange box 2 and immersed in the cooling liquid 5. Specifically, the refrigeration machine 3 is operated with a refrigeration cycle to conduct a low-temperature refrigerant to flow through the refrigerant pipe 31 immersed in the cooling liquid 5 in a repeated cyclic manner.

In a preferred embodiment of the present invention, the cooling liquid 5 is a non-conductive cooling liquid.

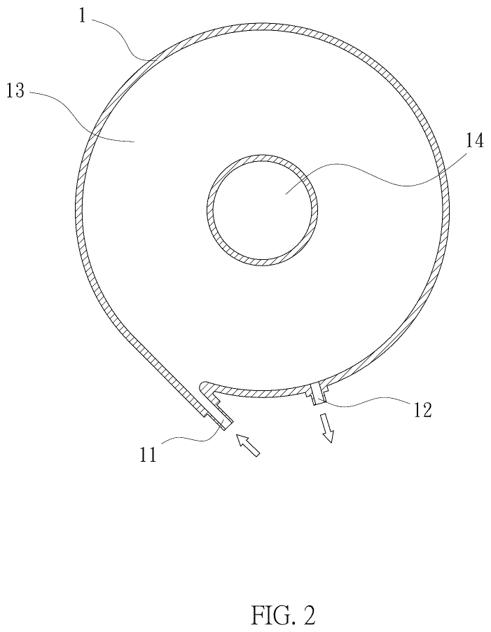

The cooling system of the present invention can be made to set the first heat exchange box 1 in a proper form according to a desired application. For example, for an application to a magnetic levitation wind power generation device, the first heat exchange box 1 is made in a cylindrical form (as shown in FIG. 2). The first cooling liquid entry opening 11 is formed in such a way that an axis thereof is in a tangential direction of a circular arc sidewall, while the first cooling liquid exit opening 12 is formed in such a way that an axis thereof is in a direction perpendicular to the circular arc sidewall. A main shaft hole 14 is formed in the center of the cylindrical form.

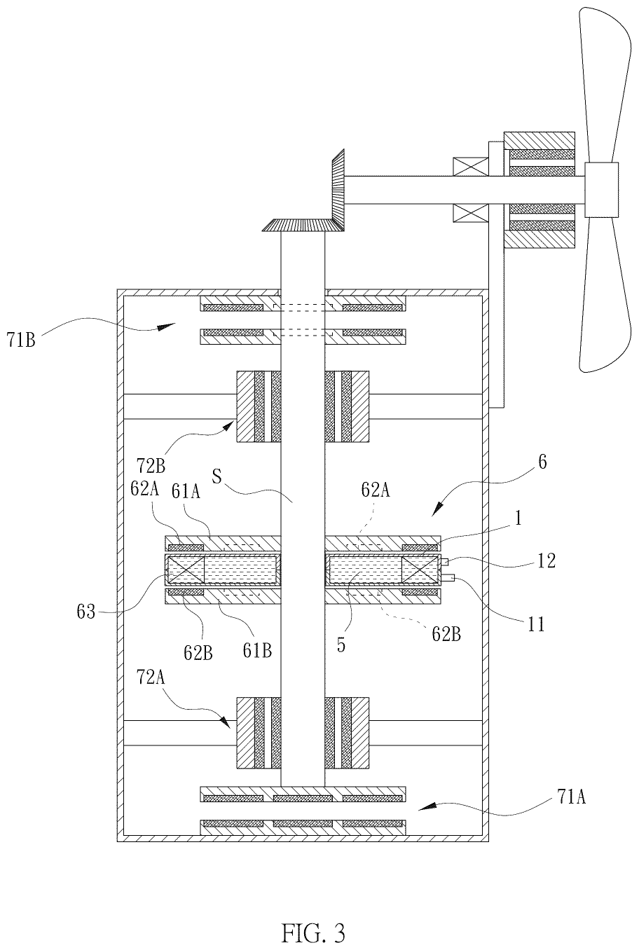

As shown in FIG. 3, the magnetic levitation wind power generation device is structured such that, in an internal space of a housing thereof, a lower magnetic levitation support seat 71A is arranged at a bottom surface, and an upper magnetic levitation support seat 71B is arranged at a top surface, and a first magnetic levitation bearing 72A and a second magnetic levitation bearing 72B are arranged in the internal space in the vertical direction; and a main shaft S is vertically arranged on the first and second magnetic levitation bearings 72A, 72B, and upper and lower ends of the main shaft S are respectively connected to the upper magnetic levitation support seat 71B and the lower magnetic levitation support seat 71A, and the upper end of the main shaft S is extended outside of the housing and is connected, by means of a transmission mechanism, such as toothed wheels, to fan blades. An electrical power generator 6 is arranged on the main shaft S between the first magnetic levitation bearing 72A and the second magnetic levitation bearing 72A. The electrical power generator 6 comprises a plurality of windings 63 that serve as a stator and a first rotary disk 61A and a second rotary disk 61B that serve as a rotor. The windings 63 are mounted to the housing along a circumference of the main shaft S and are connected to a power transmission line. The first rotary disk 61A and the second rotary disk 61B are mounted on the main shaft S, and the first rotary disk 61A and the second rotary disk 61B are respectively provided with a plurality of first induction magnets 62A and second induction magnets 6B arranged along circumferences thereof. The first induction magnets 62A and the second induction magnets 6B, when rotated relative to the windings 63, generate an induction current, and such a current is outputted through the power transmission line. During operation, fan blades drive, through the transmission mechanism, the main shaft S to rotate to have the first and second rotary disks 61A, 61B of the electrical power generator 6 rotating to generate electrical power.

In the cooling system of the present invention, the first heat exchange box 1 functions to contain, in a closed and hermetical manner, the electrical power generator 6, and when the first heat exchange box 1 is full of the cooling liquid 5, the windings 63 of the electrical power generator 6 are completely immersed in the cooling liquid 5 contained in the first heat exchange box 1.

As the operation of the electrical power generator 6 causes the windings 63 to generate heat, after the cooling system of the present invention is activated, the refrigeration machine 3 is in operation to cause the refrigerant to circulate and flow through the refrigerant pipe 31, and therefore, the refrigerant of which the temperature has been lowered performs, through the refrigerant pipe 31, heat exchange with the cooling liquid 5 of the second heat exchange box 2, and the cooling liquid 5, with the temperature being so lowered, is drawn by the pump 4 to move through the second pipe 24 and get into the first heat exchange box 1 to perform heat exchange with, and absorb heat from, the electrical power generator 6. The cooling liquid 5 of which the temperature has increased in the first heat exchange box 1 then moves through the first pipe 23 to return back to the interior of the second heat exchange box 2 to once again carry out heat exchange with the refrigerant pipe 31 to have the temperature thereof lowered down, and the cooling liquid 5 of which the temperature is so lowered down is then fed again into the first heat exchange box 1 to carry out heat exchange with the electrical power generator 6, and such a process is so performed cyclically. As such, heat of the electrical power generator can be reduced with high efficiency, and there is no need to use heat dissipating fins in combination with air cooling.

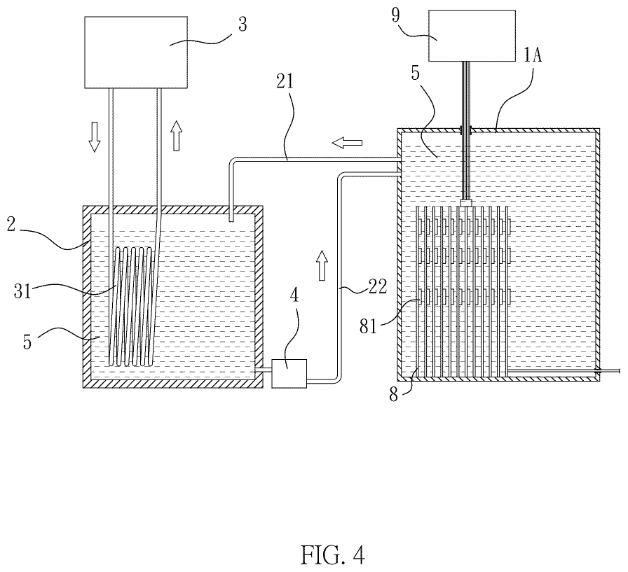

As shown in FIG. 4, when high-end chips are in operation and generate a large amount of heat, as the known ways of air cooling and heat dissipating no long meet the requirements, a plurality of circuit boards 8 on which chips 81 are mounted are placed into a first heat exchange box 1A that is made in a rectangular parallelepiped form, and the circuit boards 8 are connected to a power supply line to the first heat exchange box 1A and are electrically connected to an externally arranged controller 9 to control circuit operation. A non-conductive cooling liquid 5 is filled into the first heat exchange box 1A and the second heat exchange box 2, such that the circuit boards 8 that carry the chips 81 are immersed in the cooling liquid 5 contained in the first heat exchange box 1A. When the refrigeration machine 3 is activated into operation to have the refrigerant circulating and flowing through the refrigerant pipe 31, the refrigerant of which the temperature has been lowered performs, through the refrigerant pipe 31, heat exchange with the cooling liquid 5 of the second heat exchange box 2, and the cooling liquid 5, with the temperature being so lowered, is drawn by the pump 4 to move through the second pipe 24 and get into the first heat exchange box 1 to perform heat exchange with, and absorb heat from, the chips 81 of the circuit boards 8 or other heat-generating bodies. The cooling liquid 5 of which the temperature has increased in the first heat exchange box 1 then moves through the first pipe 23 to return back to the interior of the second heat exchange box 2 to once again carry out heat exchange with the refrigerant pipe 31 to have the temperature thereof lowered down, and the cooling liquid 5 of which the temperature is so lowered down is then fed again into the first heat exchange box 1 to carry out heat exchange with the chips 81 and other heat-generating bodies, and such a process is so performed cyclically.

The present invention provides the above-described cooling system to hermetically enclose the cooling liquid in the first heat exchange box 1, 1A and the second heat exchange box 2 for circulating and flowing therebetween, so as to exhibit advantages of being free of leakage of coolant vapor and ensuring better cold-keeping for the cooling liquid circulating internally.

I claim:

1. At closed-type heat-dissipating-fin-free cooling-liquid-immersed cooling system, comprising:
a first heat exchange box, which contains therein a heat-generating body, the first heat exchange box comprising a first cooling liquid entry opening and a first cooling liquid exit opening;
a second heat exchange box, which contains a cooling liquid, the second heat exchange box comprising a second cooling liquid entry opening and a second cooling liquid exit opening, wherein the second cooling liquid entry opening and the first cooling liquid exit opening are connected through a first pipe, and the second cooling liquid exit opening and the first cooling liquid entry opening are connected through a second pipe, and a pump is arranged on the second pipe; and
a refrigeration machine, which is connected with a refrigerant pipe, the refrigerant pipe being extended into an interior of the second heat exchange box and immersed in the cooling liquid;
wherein the refrigeration machine causes a refrigerant to circulate and flow through the refrigerant pipe to have temperature-lowered refrigerant perform, through the refrigerant pipe, heat exchange with the cooling liquid contained in the second heat exchange box, and the cooling liquid, of which temperature is lowered is drawn by the pump and fed through the second pipe into the first heat exchange box to carry out heat exchange with, and absorb heat from, the heat-generating body, and the cooling liquid of which the temperature increases, flows through the first pipe to return back into the second heat exchange box to carry out heat exchange again to lower down the temperature thereof, so as to proceed cyclically.

2. The closed-type heat-dissipating-fin-free cooling-liquid-immersed cooling system according to claim 1, wherein the cooling liquid is a non-conductive cooling liquid.

3. The closed-type heat-dissipating-fin-free cooling-liquid-immersed cooling system according to claim 2, wherein the first heat exchange box is of a cylindrical form, and the first cooling liquid entry opening is formed so that an axis thereof is in a tangential direction of a circular arc sidewall.

4. The closed-type heat-dissipating-fin-free cooling-liquid-immersed cooling system according to claim 3, wherein the first cooling liquid exit opening is formed so that an axis thereof is in a direction perpendicular to the circular arc sidewall.

5. The closed-type heat-dissipating-fin-free cooling-liquid-immersed cooling system according to claim 4, wherein a main shaft hole is formed in a center of the cylindrical form.

6. The closed-type heat-dissipating-fin-free cooling-liquid-immersed cooling system according to claim 5, wherein the first heat exchange box contains an electrical power generator of a magnetic levitation power generation device therein, such that windings of the electrical power generator are completely immersed in the cooling liquid in the first heat exchange box, a main shaft of the electrical power generator extending through the main shaft hole.

7. The closed-type heat-dissipating-fin-free cooling-liquid-immersed cooling system according to claim 2, wherein the first heat exchange box is of a rectangular parallelepiped form in which circuit boards on which chips are mounted are received.
